(19) United States
(12) Patent Application Publication
(10) Pub. No.: US 2008/0053518 A1
(43) Pub. Date: Mar. 6, 2008

(54) TRANSPARENT SOLAR CELL SYSTEM

(76) Inventors: Pen-Hsiu Chang, Kwei-Shan (TW); Hsin-Chun Lu, Kwei-Shan (TW); Ching-Ting Lee, Tainan City (TW); Lain-Be Chang, Kwei-Shan (TW); Gwo-Mei Wu, Kwei-Shan (TW); Nai-Chuan Chen, Kwei-Shan (TW); An-Ping Chiu, Kwei-Shan (TW)

Correspondence Address: SINORICA, LLC, 528 FALLSGROVE DRIVE, ROCKVILLE, MD, 20850, US

(21) Appl. No.: 11/469,918

(22) Filed: Sep. 5, 2006

(51) Int. Cl. H01L 31/00

(52) U.S. Cl. 136/252; 136/255

(57) ABSTRACT

The present invention discloses a transparent solar cell system, which comprises: a light-permeable solar energy conversion device, balance units and conductive wires. The light-permeable solar energy conversion device has a transparent photovoltaic element, which is a PN semiconductor structure formed of two transparent conductive films. The transparent conductive films are respectively made of different oxides. The substrate of the transparent solar cell system is made of a common glass or a common plastic; therefore, the transparent solar cell system of the present invention is lightweight and environment-friendly. Further, the present invention has a simple fabrication process and a low fabrication cost; therefore, the present invention can be extensively applied to the windows and doors of buildings and vehicles and benefits the popularization of solar energy.

### BACKGROUND OF THE INVENTION

1. Field of the Invention

The present invention relates to a solar cell system, particularly to a transparent solar cell system.

2. Description of the Related Art

As the traditional energy resources, such as petroleum, coal and natural gas, are gradually exhausted, alternative energies have become important science and technology objectives. To avoid the reappearance of the serious environmental pollution the fossil fuels has brought about, the alternative energies had better be clean enough in addition to inexhaustibility. Thus, solar energy becomes the best choice among the alternative energies.

There have been various types of solar cells appearing since the Bell Laboratory proposed the technology of solar cells in 1954 firstly. However, most of them are made of dark-color materials having very low light transmittances, such as polysilicon, non-crystalline silicon, copper-indium-gallium diselenide, a silicon film, a cadmium-tellurium film, and a photosensitization dye. The large-area and heavy conventional solar cell system can only be installed on the roof. However, they are usually blown away during a typhoon or a tornado, which will endanger the public safety. If the conventional solar cell system is used to take the place of the windows and doors of buildings, sunlight will be retarded by the opaque solar cells; thus, more energy than the solar cells generate will be needed to illuminate the buildings. If the conventional solar cell system is installed on a vehicle, the solar cell system generating enough energy to drive the vehicle may weigh half the weight of the vehicle. When used in vehicles, the conventional solar cell system seems to consume more energy than it generates. Besides, the conventional solar cells, which are made of the abovementioned polysilicon, non-crystalline silicon, copper-indium-gallium diselenide, silicon film, cadmium-tellurium film or photosensitization dye, can only absorb the longer-wavelength spectrum of sunlight; thus, the energy-conversion efficiency thereof is always hard to promote effectively.

Solar cell systems have been widely studied in the field concerned recently. For example, a Taiwan patent No. 239657 proposed a “solar cell and a module thereof”, wherein as shown in FIG. 1, a single solar cell comprises: an anode layer 610, a photovoltaic layer 630, a cathode layer 620 and a sealing layer 640; the anode layer 610 and the cathode layer 620 clamp the photovoltaic layer 630 and respectively project from the ends of the photovoltaic layer 630; more than one sealing layer 640 is installed at the ends of the photovoltaic layer 630 and used to seal the photovoltaic layer 630; and the solar cells are interconnected parallel or in series to form a solar cell module. However, the abovementioned solar cell is made of the existing materials and hard to contribute to the performance of the solar cell systems.

To overcome the abovementioned problems, the present invention proposes a transparent solar cell system, wherein different materials are used to fabricate a light-permeable solar cell system that can absorb a great amount of short-wavelength light, such as ultraviolet light. Further, as the solar cell system proposed by the present invention is transparent, it can take the place of glass and can be used as the transparent partitions of buildings and can thus benefit the popularization of solar energy.

### SUMMARY OF THE INVENTION

The primary objective of the present invention is to provide a transparent solar cell system, which can absorb the shorter-wavelength spectrum of sunlight, such as ultraviolet light, and can thus promote the energy-conversion efficiency, and which has a simple and lightweight structure and can thus simplify the fabrication process and reduce the fabrication cost. Via the promoted energy-conversion efficiency and the reduced cost, the present invention can thus expand the application fields of solar cells and benefit the popularization of solar cells.

Another objective of the present invention is to provide a transparent solar cell system, which is a mixed type solar energy conversion device comprising a transparent solar energy conversion device and an opaque solar energy conversion device, whereby the energy-conversion efficiency of solar cells is greatly promoted; the service life of solar cells is extended; and the application fields of solar cells is expanded.

To achieve the abovementioned objectives, the present invention proposes a transparent solar cell system, which comprises a light-permeable solar energy conversion device. The light-permeable solar energy conversion device further comprises: a transparent substrate, a first electrode, a transparent photovoltaic element and a second electrode. The transparent substrate may be made of glass, quartz, sapphire, a transparent plastic, a transparent flexible material or the like. The transparent photovoltaic element is formed of transparent conductive oxides and further comprises: a first transparent conductive film and a second transparent conductive film. The first transparent conductive film may be a transparent P-type semiconductor material and may be selected from the group consisting of copper-aluminum oxide, copper-gallium oxide, copper-scandium oxide, copper-chromium oxide, copper-indium oxide, copper-yttrium oxide, silver-indium oxide and the similar transparent conductive oxides. The second transparent conductive film may be a transparent N-type semiconductor material and may be selected from the group consisting of zinc oxide, tin oxide, indium-zinc oxide, indium-tin oxide and the similar transparent conductive oxides. The abovementioned first transparent conductive film and second transparent conductive film are interchangeable. The abovementioned transparent substrate, first electrode, first transparent conductive film, second transparent conductive film and second electrode are disposed sequentially from bottom to top. The abovementioned light-permeable solar energy conversion device absorbs the shorter-wavelength spectrum of sunlight, such as the sunlight with the wavelengths within 350 to 600 nm. Further, the abovementioned light-permeable solar energy conversion device may be incorporated with an opaque solar energy conversion device to form a mixed type solar energy conversion device. The materials of the opaque solar energy conversion device may be selected from the group consisting of polysilicon, non-crystalline silicon, copper-indium-gallium diselenide, a silicon film, a cadmium-tellurium film, a photosensitization dye, a II-VI group compound, a III-V group compound, and the similar materials. The opaque solar energy conversion device can absorb the sunlight of longer wavelengths that the light-permeable solar energy conversion device does not absorb. Either of the light-permeable solar energy conversion device and the mixed type solar energy conversion device is electrically connected to balance units, and peripheral elements with conductive wires to complete the transparent solar cell system of the present invention. The transparent solar cell system of the present invention can effectively convert solar energy into electric energy. Further, the transparent solar cell system of the present invention can take the place of glass and provide electric energy for a building without sunlight obstruction.

To enable the objectives, technical contents, characteristics and accomplishments of the present invention to be easily understood, the embodiments of the present invention are to be described in detail in cooperation with the attached drawings.

### BRIEF DESCRIPTION OF THE DRAWINGS

FIG. 1 is a sectional view schematically showing a conventional solar cell;

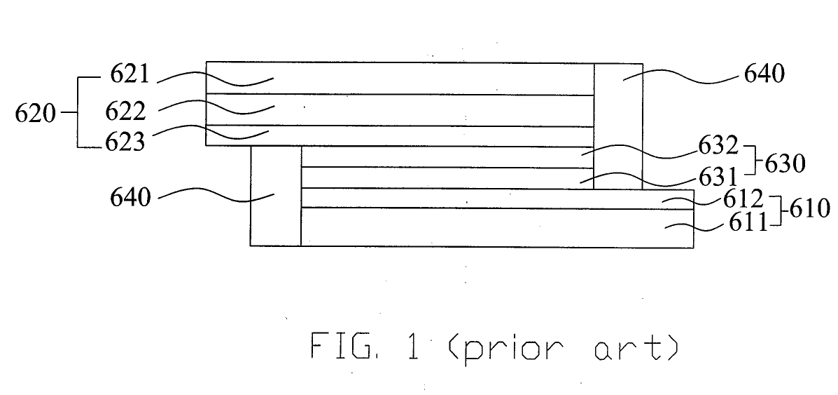

FIG. 2 is a sectional view schematically showing the light-permeable solar energy conversion device according to the present invention;

FIG. 3 is a top view schematically showing the comb-like electrode structure in the light-permeable solar energy conversion device according to the present invention;

FIG. 4 is a diagram schematically showing the equivalent circuit of the transparent solar cell system according to the present invention; and

FIG. 5 is a diagram schematically showing the appearance of the mixed type solar energy conversion device according to the present invention.

### DETAILED DESCRIPTION OF THE INVENTION

Solar energy is a very important means for power supply and environmental protection. However, the conventional solar cell systems made of copper-indium-gallium diselenide, a cadmium-tellurium film or a photosensitization dye will harm the environment when they are abandoned. Further, the conventional solar cells adopt dark-color or opaque materials; therefore, it is not so easy to apply the conventional solar cells to the living surroundings. Accordingly, the present invention proposes a transparent solar cell system, which has a higher energy-conversion efficiency and an extensive applicability. Below, the embodiments of the present invention are to be described in detail in cooperation with the drawings.

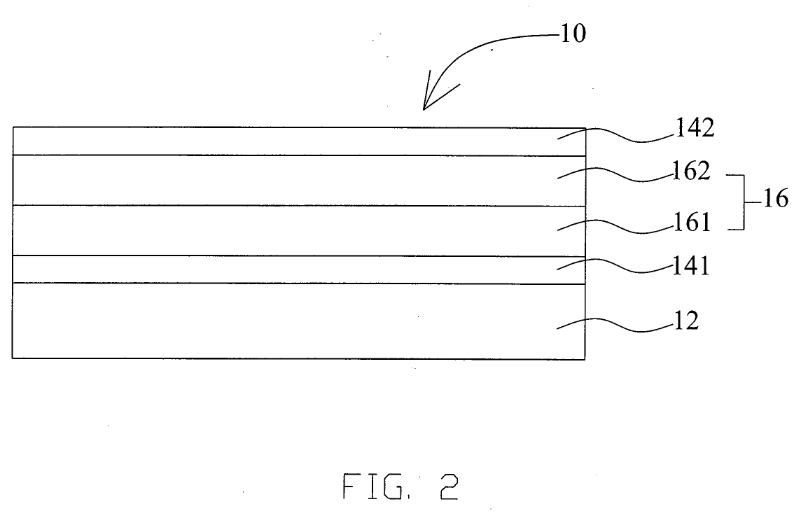

Refer to FIG. 2 a sectional view schematically showing the light-permeable solar energy conversion device according to the present invention. As shown in FIG. 2, the light-permeable solar energy conversion device 10 of the present invention comprises: a transparent substrate 12, a first electrode 141, a transparent photovoltaic element 16 and a second electrode 142. The transparent photovoltaic element 16 further comprises: a first transparent conductive film 161 and a second transparent conductive film 162. The transparent substrate 12 is made of glass, quartz, sapphire, a transparent plastic, a transparent flexible material or the like. The first electrode 141 and the second electrode 142 is made of a metallic material with a superior conductivity. Both the first transparent conductive film 161 and the second transparent conductive film 162 are respectively made of different transparent conductive oxides, such as a transparent P-type oxide semiconductor material and a transparent N-type oxide semiconductor material. When the first transparent conductive film 161 is made of a transparent P-type oxide semiconductor material, the second transparent conductive film 162 is made of a transparent N-type oxide semiconductor material; when the first transparent conductive film 161 is made of a transparent N-type oxide semiconductor material, the second transparent conductive film 162 is made of a transparent P-type oxide semiconductor material, i.e. the materials of the first transparent conductive film 161 and the second transparent conductive film 162 are interchangeable. The transparent P-type oxide semiconductor material may be selected from the group consisting of copper-aluminum oxide, copper-gallium oxide, copper-scandium oxide, copper-chromium oxide, copper-indium oxide, copper-yttrium oxide, silver-indium oxide and the similar transparent conductive oxides. The transparent N-type semiconductor material may be selected from the group consisting of zinc oxide, tin oxide, indium-zinc oxide, indium-tin oxide and the similar transparent conductive oxides. The abovementioned transparent substrate 12, first electrode 141, first transparent conductive film 161, second transparent conductive film 162 and second electrode 142 are disposed sequentially from bottom to top. Different methods are used to form the abovementioned structures. For example, an electroplating method is usually used to form the first electrode 141 and the second electrode 142 when they are made of a metallic material; a vapor deposition method or a sputtering method is usually used to form the first transparent conductive film 161 and the second transparent conductive film 162.

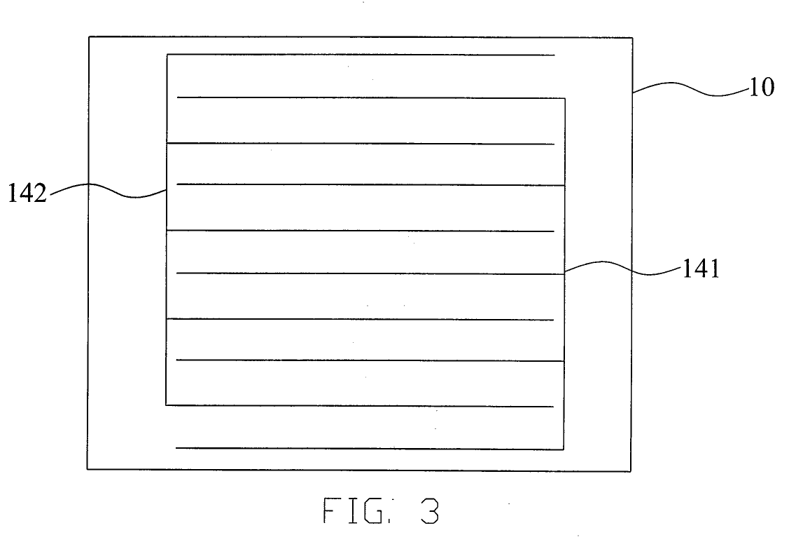

From those described above, it is known: among the structures of the light-permeable solar energy conversion device 10 of the present invention, the transparent substrate 12, the first transparent conductive film 161 and the second transparent conductive film 162 are all light-permeable except the first and second electrodes 141 and 142. However, the second electrodes 142 happen to be on the topmost layer of the light-permeable solar energy conversion device 10. Therefore, in the present invention, when made of an opaque material, the electrodes are fabricated into a finger-like structure, a network structure or a comb-like structure lest sunlight be obscured. Refer to FIG. 3 a top view schematically showing the comb-like electrode structure in the light-permeable solar energy conversion device 10 according to the present invention. In the embodiment shown in FIG. 3, the first electrode 141 and the second electrode 142 are arranged alternately; however, in other embodiments of the present invention, the first electrode 141 and the second electrode 142 are not necessarily arranged alternately.

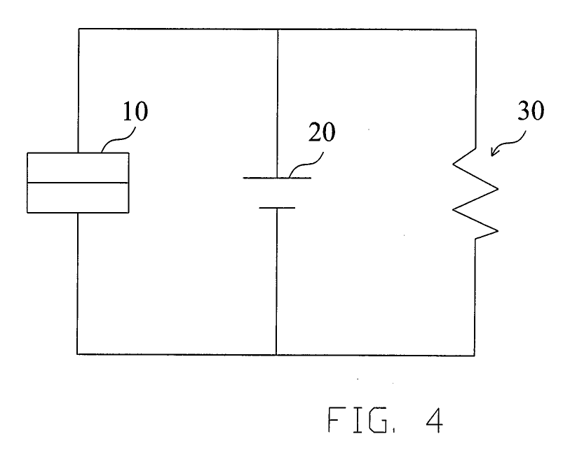

The light-permeable solar energy conversion device of the present invention has been described above. However, the above-mentioned light-permeable solar energy conversion device 10 has to further electrically connect to balance units, such as an energy-storage device, a power regulator and a structure-fixing device, to complete the transparent solar cell system of the present invention, so that the energy acquired by the light-permeable solar energy conversion device 10 can be stored and utilized. The light-permeable solar energy conversion device 10 is connected to the balance units with conductive wires, which are made of a metallic material with a high conductivity, such as copper, silver, gold or aluminum. Refer to FIG. 4 a diagram schematically showing the equivalent circuit of the solar cell system of the present invention, wherein the light-permeable solar energy conversion device 10 is regarded as a power supply and connected to a battery 20 and a resistor 30 to form a circuit.

Further, the present invention also proposes a mixed type solar energy conversion device, which comprises: a light-permeable solar energy conversion device and an opaque solar energy conversion device. The mixed type solar energy conversion device is to be described below.

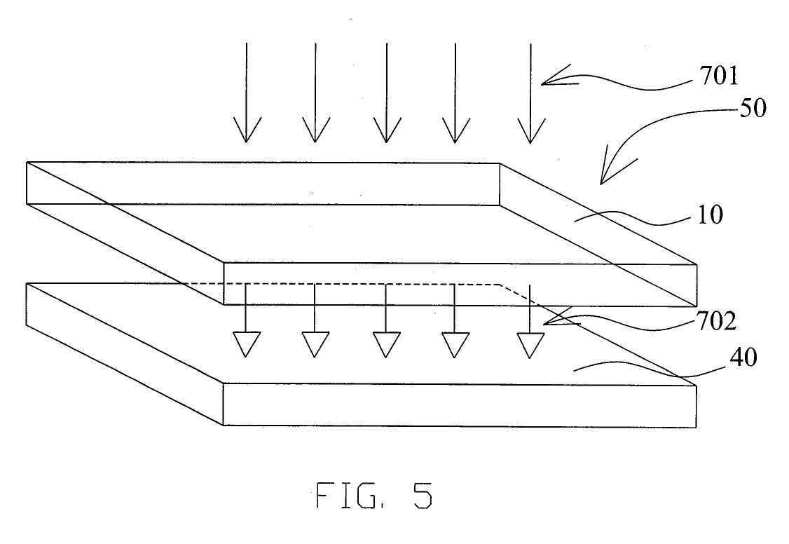

Refer to FIG. 5 a diagram schematically showing the appearance of the mixed type solar energy conversion device according to the present invention. In the mixed type solar energy conversion device 50, the light-permeable solar energy conversion device 10 is disposed above the opaque solar energy conversion device 40. When the original sunlight 701 hits on the light-permeable solar energy conversion device 10, the short-wavelength spectrum of the original sunlight 701 is absorbed and converted into electric energy by the light-permeable solar energy conversion device 10. The longer-wavelength spectrum 702 of the original sunlight 701 passes through the light-permeable solar energy conversion device 10 and hits on the opaque solar energy conversion device 40 and is absorbed and converted into electric energy by the opaque solar energy conversion device 40.

The mixed type solar energy conversion device 50 of the present invention has been described above. Similarly, the mixed type solar energy conversion device 50 has to further electrically connect to balance units, such as an energy-storage device, a power regulator and a structure-fixing device, to form a complete mixed type solar cell system, so that the energy acquired by the mixed type solar energy conversion device 50 can be stored and utilized. The mixed type solar energy conversion device 50 is connected to the balance units with conductive wires, which are made of a metallic material with a high conductivity, such as copper, silver, gold or aluminum.

The light-permeable solar energy conversion device can absorb the light of the wavelengths ranging from 350 to 600 nm. For the light-permeable solar energy conversion device of the present invention, the light transmittance is about 40% at the wavelength of 500 nm, and the transmittance of infrared light is about 70% max. On the whole, the energy-conversion efficiency of the light-permeable solar energy conversion device of the present invention is about 12%.

In summary, when the transparent solar cell system is only implemented with the light-permeable solar energy conversion device, it has the advantages of lightweightness and transparency and has the electromagnetic protection provided by the metallic electrodes and can be extensively applied to the designs of windows and doors of houses, offices, factories and vehicles. Further, as the transparent solar cell system of the present invention has a simple fabrication process and a low fabrication cost, it benefits the popularization of solar energy. Furthermore, the transparent solar cell system can be incorporated with the opaque solar cell system to form the mixed type solar cell system to convert a wider spectrum of sunlight into electric energy. If the temperature regulation function of infrared light is also taken into consideration, the utilization efficiency of sunlight will be as high as about 50%. Before reaching the opaque solar cell system of the mixed type solar cell system, most of the high-energy shorter-wavelength spectrum of sunlight, such as ultraviolet light, has been absorbed by the transparent solar cell system; therefore, the damage of the opaque solar cell system induced by ultraviolet light is reduced, and the service life of the mixed type solar cell system of the present invention is extended.

Those described above are the embodiments to exemplify the present invention to enable the person skilled in the art to understand, make and use the present invention. However, it is not intended to limit the scope of the present invention. Any equivalent modification and variation according to the spirit of the present invention is to be also included within the scope of the claims of the present invention stated below.

What is claimed is:

1. A light-permeable solar energy conversion device, comprising:
a transparent substrate;
a first electrode formed on said transparent substrate;
a transparent photovoltaic element formed on said first electrode; and
a second electrode formed on said transparent photovoltaic element.

2. The light-permeable solar energy conversion device according to claim 1, wherein said photovoltaic element is formed of transparent conductive oxides and further comprises:
a first transparent conductive film formed on said first electrode; and
a second transparent conductive film formed on said first transparent conductive film.

3. The light-permeable solar energy conversion device according to claim 2, wherein said first transparent conductive film is a transparent P-type semiconductor film, and said second transparent conductive film is a transparent N-type semiconductor film; said first transparent conductive film is a transparent N-type semiconductor film, and said second transparent conductive film is a transparent P-type semiconductor film.

4. The light-permeable solar energy conversion device according to claim 3, wherein material of said transparent P-type semiconductor film is selected from the group of transparent conductive oxides consisting of copper-aluminum oxide, copper-gallium oxide, copper-scandium oxide, copper-chromium oxide, copper-indium oxide, copper-yttrium oxide, silver-indium oxide.

5. The light-permeable solar energy conversion device according to claim 3, wherein material of said transparent N-type semiconductor film is selected from the group of transparent conductive oxides consisting of zinc oxide, tin oxide, indium-zinc oxide, indium-tin oxide.

6. The light-permeable solar energy conversion device according to claim 1, wherein material of said transparent substrate is selected from the group consisting of glass, quartz, sapphire, transparent plastics, transparent flexible materials.

7. The light-permeable solar energy conversion device according to claim 1, wherein said first electrode is a transparent electrode.

8. The light-permeable solar energy conversion device according to claim 1, wherein said second electrode is a transparent electrode.

9. The light-permeable solar energy conversion device according to claim 1, wherein said first electrode is a non-transparent electrode and has a structure with at least one transparent area.

10. The light-permeable solar energy conversion device according to claim 9, wherein said first electrode has a finger-like structure, a network-like structure, or a comb-like structure.

11. The light-permeable solar energy conversion device according to claim 1, wherein said second electrode is a non-transparent electrode and has a structure with at least one transparent area.

12. The light-permeable solar energy conversion device according to claim 9, wherein said second electrode has a finger-like structure, a network-like structure, or a comb-like structure.

13. A light-permeable solar energy storage system, comprising:
at least one light-permeable solar energy conversion device each including:
a transparent substrate,
a first electrode formed on said transparent substrate,
a transparent photovoltaic element formed on said first electrode, and
a second electrode formed on said transparent photovoltaic element; and
at least one balance unit electrically connected to said light-permeable solar energy conversion device with at least one conductive wire.

14. The light-permeable solar energy storage system according to claim 13, wherein said photovoltaic element is formed of transparent conductive oxides and further comprises:
a first transparent conductive film formed on said first electrode; and
a second transparent conductive film formed on said first transparent conductive film.

15. The light-permeable solar energy storage system according to claim 14, wherein said first transparent conductive film is a transparent P-type semiconductor film, and said second transparent conductive film is a transparent N-type semiconductor film; said first transparent conductive film is a transparent N-type semiconductor film, and said second transparent conductive film is a transparent P-type semiconductor film.

16. The light-permeable solar energy storage system according to claim 15, wherein material of said transparent P-type semiconductor film is selected from the group of transparent conductive oxides consisting of copper-aluminum oxide, copper-gallium oxide, copper-scandium oxide, copper-chromium oxide, copper-indium oxide, copper-yttrium oxide, silver-indium oxide.

17. The light-permeable solar energy storage system according to claim 15, wherein material of said transparent N-type semiconductor film is selected from the group of transparent conductive oxides consisting of zinc oxide, tin oxide, indium-zinc oxide, indium-tin oxide.

18. The light-permeable solar energy storage system according to claim 13, wherein material of said transparent substrate is selected from the group consisting of glass, quartz, sapphire, transparent plastics, transparent flexible materials and the likes.

19. The light-permeable solar energy storage system according to claim 13, wherein said first electrode is a transparent electrode.

20. The light-permeable solar energy storage system according to claim 13, wherein said second electrode is a transparent electrode.

21. The light-permeable solar energy storage system according to claim 13, wherein said first electrode is a non-transparent electrode and has a structure with at least one transparent area for light penetration.

22. The light-permeable solar energy storage system according to claim 21, wherein said first electrode has a finger-like structure, a network-like structure, or a comb-like structure.

23. The light-permeable solar energy storage system according to claim 13, wherein said second electrode is a non-transparent electrode and has a structure with at least one transparent area for light penetration.

24. The light-permeable solar energy storage system according to claim 23, wherein said second electrode has a finger-like structure, a network-like structure, or a comb-like structure.

25. The light-permeable solar energy storage system according to claim 13, wherein said light-permeable solar energy conversion device has an electromagnetic-protection function.

26. The light-permeable solar energy storage system according to claim 13, wherein said balance unit further comprises: an energy storage device, a power regulator and a structure-fixing device.

27. The light-permeable solar energy storage system according to claim 13, wherein said conductive wires further connect to external peripheral elements.

28. The light-permeable solar energy storage system according to claim 13, wherein the material of said conductive wires is selected from the group consisting of copper, silver, gold, aluminum, and other high-conductivity metallic materials.

29. A mixed type solar energy conversion device, comprising:
at least one light-permeable solar energy conversion device each including:
a transparent substrate,
a first electrode formed on said transparent substrate,
a transparent photovoltaic element formed on said first electrode, and
a second electrode formed on said transparent photovoltaic element; and
at least one opaque solar energy conversion device installed below said light-permeable solar energy conversion device to absorb the light penetrating through said light-permeable solar energy conversion device.

30. The mixed type solar energy conversion device according to claim 29, wherein said photovoltaic element is formed of transparent conductive oxides and further comprises:
a first transparent conductive film formed on said first electrode; and
a second transparent conductive film formed on said first transparent conductive film.

31. The mixed type solar energy conversion device according to claim 30, wherein said first transparent conductive film is a transparent P-type semiconductor film, and said second transparent conductive film is a transparent N-type semiconductor film; said first transparent conductive film is a transparent N-type semiconductor film, and said second transparent conductive film is a transparent P-type semiconductor film.

32. The mixed type solar energy conversion device according to claim 31, wherein material of said transparent P-type semiconductor film is selected from the group of transparent conductive oxides consisting of copper-aluminum oxide, copper-gallium oxide, copper-scandium oxide, copper-chromium oxide, copper-indium oxide, copper-yttrium oxide, silver-indium oxide.

33. The mixed type solar energy conversion device according to claim 31, wherein material of said transparent N-type semiconductor film is selected from the group of transparent conductive oxides consisting of zinc oxide, tin oxide, indium-zinc oxide, indium-tin oxide.

34. The mixed type solar energy conversion device according to claim 29, wherein material of said transparent substrate is selected from the group consisting of glass, quartz, sapphire, transparent plastics, transparent flexible materials.

35. A mixed type solar cell system, comprising:
at least one light-permeable solar energy conversion device each including:
a transparent substrate,
a first electrode formed on said transparent substrate,
a transparent photovoltaic element formed on said first electrode, and
a second electrode formed on said transparent photovoltaic element;
at least one opaque solar energy conversion device installed below said light-permeable solar energy conversion device to absorb the light penetrating through said light-permeable solar energy conversion device; and
at least one balance unit electrically connected to said light-permeable solar energy conversion device and said opaque solar energy conversion device with a plurality of conductive wires.

36. The mixed type solar cell system according to claim 35, wherein said photovoltaic element is formed of transparent conductive oxides and further comprises:
a first transparent conductive film formed on said first electrode; and
a second transparent conductive film formed on said first transparent conductive film.

37. The mixed type solar cell system according to claim 36, wherein said first transparent conductive film is a transparent P-type semiconductor film, and said second transparent conductive film is a transparent N-type semiconductor film; said first transparent conductive film is a transparent N-type semiconductor film, and said second transparent conductive film is a transparent P-type semiconductor film.

38. The mixed type solar cell system according to claim 37, wherein material of said transparent P-type semiconductor film is selected from the group of transparent conductive oxides consisting of copper-aluminum oxide, copper-gallium oxide, copper-scandium oxide, copper-chromium oxide, copper-indium oxide, copper-yttrium oxide, silver-indium oxide.

39. The mixed type solar cell system according to claim 37, wherein material of said transparent N-type semiconductor film is selected from the group of transparent conductive oxides consisting of zinc oxide, tin oxide, indium-zinc oxide, indium-tin oxide.

40. The mixed type solar cell system according to claim 35, wherein material of said transparent substrate is selected from the group consisting of glass, quartz, sapphire, transparent plastics, transparent flexible materials.
